(19) United States
(12) Patent Application Publication
(10) Pub. No.: US 2026/0271487 A1
(43) Pub. Date: Sep. 10, 2026

(54) LIGHT-EMITTING ELEMENT, DISPLAY DEVICE, METHOD FOR PRODUCING LIGHT-EMITTING ELEMENT, AND METHOD FOR RESTORING EMISSION CHARACTERISTIC OF LIGHT-EMITTING ELEMENT

(71) Applicant: Sharp Display Technology Corporation, Kameyama City, Mie (JP)

(72) Inventor: TAKAHIRO DOE, Sakai City, Osaka (JP)

(21) Appl. No.: 18/869,436

(22) PCT Filed: Jul. 19, 2022
(86) PCT No.: PCT/JP2022/028003

§ 371 Date: Nov. 26, 2024

(51) Int. Cl. H10K 50/115; H10K 59/12; H10K 59/80; H10K 71/00

(52) U.S. Cl. CPC H10K 50/115; H10K 59/1201; H10K 59/8794; H10K 71/861

(57) ABSTRACT

A light-emitting element includes: a first electrode; a second electrode; and a light-emitting layer provided between the first electrode and the second electrode. The light-emitting layer contains: quantum dots; and a metal halide having a melting point of 200° C. or below.

### TECHNICAL FIELD

The present disclosure relates to a light-emitting element, a display device, a method for producing a light-emitting element, and a method for restoring an emission characteristic of a light-emitting element.

### BACKGROUND ART

In recent years, display devices including OLEDs and quantum-dot light-emitting diodes (QLEDs); that is, light-emitting elements containing quantum dots, have been significantly attracting attention because such display devices operate on lower power, have a thinner profile, and achieve higher image quality.

For example, Patent Document 1 describes a nanocrystal particle containing fluorine, that is, a quantum dot a core and a shell of which at least partially contain fluorine.

### CITATION LIST

### Patent Literature

[Patent Document 1] Japanese Unexamined Patent Application Publication No. 2015-147726

### SUMMARY

### Technical Problems

It is known that, as to quantum dots containing ligands, some of the ligands are desorbed from the quantum dots with the passage of time. In various degrees, such desorption of the ligands occurs in the same manner to organic ligands and halogen ligands such as fluorine.

Hence, the light-emitting element including the quantum dots described in Patent Document 1, containing fluorine, and serving as a light-emitting layer, and a display device including the light-emitting element have problems; that is, it is difficult to ensure long-term reliability of the light-emitting layer containing the quantum dots, and it is impossible to avoid a decrease, with the passage of time, in emission characteristic (light emission efficiency) of the light-emitting layer containing the quantum dots.

An aspect of the present disclosure is conceived in view of the above problems, and sets out to provide a light-emitting element and a display device that can improve long-term reliability of a light-emitting layer containing quantum dots and restore a decreased emission characteristic (light emission efficiency). The aspect sets out to also provide a method for producing the light-emitting element and a method for restoring an emission characteristic of the light-emitting element.

### Solution to Problems

In order to solve the above problems, a light-emitting element according to the present disclosure includes:
a first electrode;
a second electrode; and
a light-emitting layer provided between the first electrode and the second electrode,
wherein the light-emitting layer contains: quantum dots; and a metal halide having a melting point of 200° C. or below.

In order to solve the above problem, a display device according to the present disclosure includes:
a display panel including the light-emitting element; and a drive circuit,
wherein, in accordance with a video signal input from outside, the drive circuit supplies a current, between the first electrode and the second electrode, at a current density selected within a first current density range, and causes the light-emitting layer to emit light at a luminance corresponding to the selected current density, and
a melting point of the metal halide is higher than a temperature observed of the light-emitting element when the current is supplied between the first electrode and the second electrode at the selected current density.

In order to solve the above problem, a display device according to the present disclosure includes:
a display panel including the light-emitting element; and
a heating unit configured to raise a temperature of the light-emitting element higher than a melting point of the metal halide.

In order to solve the above problem, a method for producing a light-emitting element according to the present disclosure includes:
a step of forming a light-emitting layer containing: quantum dots; and a metal halide having a melting point of 200° C. or below.

In order to solve the above problem, a method according to the present disclosure is directed to restoration of an emission characteristic of the light-emitting element produced by the method for producing the light-emitting element.

The method for restoring the emission characteristic includes
a step of melting the metal halide.

### Advantageous Effects of Disclosure

An aspect of the present disclosure can provide a light-emitting element and a display device that can improve long-term reliability of a light-emitting layer containing quantum dots and restore a decreased emission characteristic (light emission efficiency). The aspect can also provide a method for producing the light-emitting element and a method for restoring an emission characteristic of the light-emitting element.

### BRIEF DESCRIPTION OF DRAWINGS

FIG. 1 is a plan view illustrating a schematic configuration of a display device according to a first embodiment.

FIG. 2 is a cross-sectional view illustrating a schematic configuration of a display region of a display panel included in the display device according to the first embodiment.

FIG. 3 is a cross-sectional view of a schematic configuration of a red light-emitting element included in the display device according to the first embodiment.

FIG. 4 is a diagram illustrating band levels of a hole transport layer, an electron transport layer, quantum dots, and a metal halide, all of which are included in the red light-emitting element illustrated in FIG. 3.

FIG. 5 is a diagram showing how a light-emitting layer changes over time after the red light-emitting element illustrated in FIG. 3 has been driven for a predetermined time period.

FIG. 6 is a graph showing a relationship between: the current density of a current flowing between a first electrode and a second electrode provided to each of a plurality of light-emitting elements of the display device according to the first embodiment; and the temperature of the light-emitting elements.

FIG. 7 is a diagram illustrating the light-emitting layer of the red light-emitting element illustrated in FIG. 5 and changed over time, and showing how a metal halide contained in the light-emitting layer is melted and an emission characteristic (light emission efficiency) of the red light-emitting element is restored.

FIG. 8 is a cross-sectional view of a schematic configuration of another red light-emitting element that can be included in the display device according to the first embodiment.

FIG. 9 is a diagram illustrating band levels of a hole transport layer, an electron transport layer, quantum dots, and a metal halide, all of which are included in a green light-emitting element of the display device according to the first embodiment.

FIG. 10 is a diagram illustrating band levels of a hole transport layer, an electron transport layer, quantum dots, and a metal halide, all of which are included in a blue light-emitting element of the display device according to the first embodiment.

FIG. 11 illustrates an example of materials that can be used as a metal halide to be contained in a light-emitting layer of each of the light-emitting elements in the respective colors, included in the display device according to the first embodiment.

FIG. 12 is a cross-sectional view illustrating a schematic configuration of a red light-emitting element included in a display device according to a second embodiment.

FIG. 13 is a diagram illustrating band levels of a hole transport layer, an electron transport layer, quantum dots, and two metal halides, all of which are included in the red light-emitting element illustrated in FIG. 12.

FIG. 14 is a diagram showing how a light-emitting layer changes over time after the red light-emitting element illustrated in FIG. 12 has been driven for a predetermined time period.

FIG. 15 is a diagram illustrating the light-emitting layer of the light-emitting element illustrated in FIG. 14 and changed over time, and showing how metal halide layers contained in the light-emitting layer are melted and an emission characteristic (light emission efficiency) of the red light-emitting element is restored.

FIG. 16 is a plan view illustrating a schematic configuration of a display device according to a third embodiment.

FIG. 17 illustrates a heating unit included in the display device illustrated in FIG. 16 according to the third embodiment.

### DESCRIPTION OF EMBODIMENTS

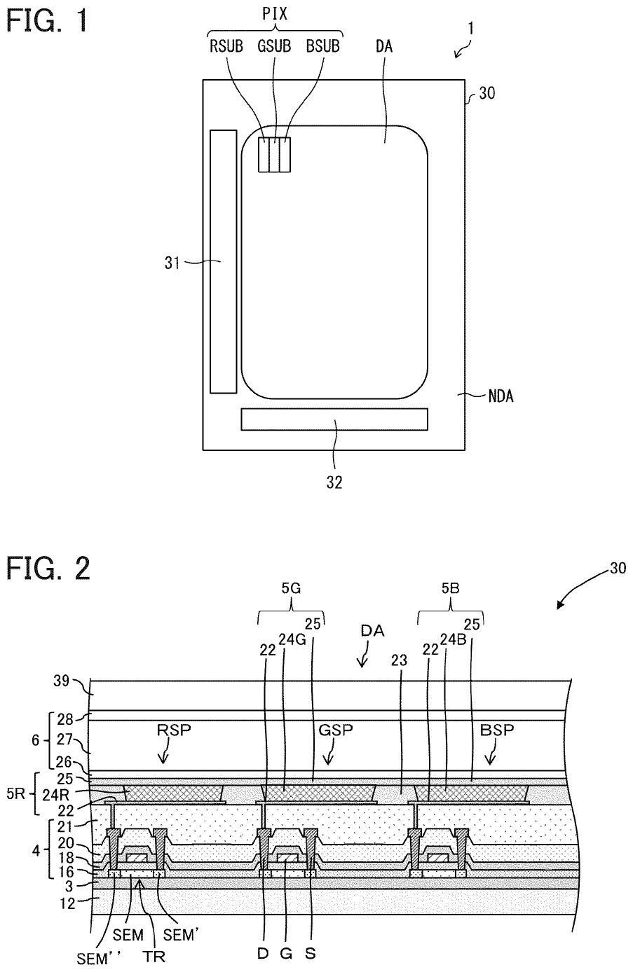

Described below are embodiments of present disclosure, with reference to FIGS. 1 to 17. For convenience in description, like reference signs designate identical constituent features throughout the embodiments. These constituent features will not be elaborated upon.

### First Embodiment

FIG. 1 is a plan view illustrating a schematic configuration of a display device 1 according to a first embodiment.

As illustrated in FIG. 1, the display device 1 includes a display panel 30. The display panel 30 includes: a picture-frame region NDA; and a display region DA. The display region DA of the display panel 30 includes a plurality of pixels PIX. Each of the pixels PIX includes: a red subpixel RSUB; a green subpixel GSUB; and a blue subpixel BSUB. This embodiment exemplifies a case where one pixel PIX includes the red subpixel RSUB, the green subpixel GSUB, and the blue subpixel BSUB. However, this embodiment shall not be limited to such a case. For example, one pixel PIX may further include a subpixel in another color, in addition to the red subpixel RSUB, the green subpixel GSUB, and the blue subpixel BSUB. Furthermore, this embodiment exemplifies a case where the picture-frame region NDA of the display panel 30 includes: a scan drive circuit 31; and a data drive circuit 32. However, this embodiment shall not be limited to such a case. At least one of the scan drive circuit 31 or the data drive circuit 32 may be externally added to the display panel 30.

FIG. 2 is a cross-sectional view illustrating a schematic configuration of the display region DA of the display panel 30 included in the display device 1 according to the first embodiment.

As illustrated in FIG. 2, the display region DA of the flexible display panel 30 included in the display device 1 includes: a barrier layer 3; a thin-film transistor layer 4 including a transistor TR; a red light-emitting element 5R, a green light-emitting element 5G, a blue light-emitting element 5B, and a bank 23; a sealing layer 6; and a functional film 39, all of which are provided in the stated order above, and from toward, a substrate 12.

The red subpixel RSUB included in the display region DA of the display panel 30 includes the red light-emitting element 5R. The green subpixel GSUB included in the display region DA of the display panel 30 includes the green light-emitting element 5G. The blue subpixel BSUB provided in the display region DA of the display panel 30 includes the blue light-emitting element 5B.

The substrate 12 may be, for example, either a resin substrate made of a resin material such as polyimide, or a glass substrate. This embodiment exemplifies a case where the display device 1 is a flexible display device, and the substrate 12 is a resin substrate made of a resin material such as polyimide. However, this embodiment shall not be limited to such a case. If the display device 1 is a non-flexible display device, the substrate 12 may be a glass substrate.

The barrier layer 3 is a layer that prevents foreign substances such as water and oxygen from entering the transistor TR, the red light-emitting element 5R, the green light-emitting element 5G, and the blue light-emitting element 5B. The barrier layer 3 may be a silicon oxide film, a silicon nitride film, or a silicon oxynitride film formed by the CVD. Alternatively, the barrier layer 3 may be a multilayer film including these films.

The thin-film transistor layer 4 including the transistor TR has a transistor TR portion. The transistor TR portion includes: a semiconductor film SEM; doped semiconductor films SEM′ and SEM″; an inorganic insulating film 16; a gate electrode G; an inorganic insulating film 18; an inorganic insulating film 20; a source electrode S; a drain electrode D; and a planarization film 21. The thin-film transistor layer 4 including the transistor TR has a portion other than the transistor TR portion. The other portion includes: the inorganic insulating film 16; the inorganic insulating film 18; the inorganic insulating film 20; and the planarization film 21.

The semiconductor films SEM, SEM′, and SEM″ may be formed of, for example, low-temperature polysilicon (LTPS) or an oxide semiconductor (e.g., an In—Ga—Zn—O-based semiconductor). This embodiment exemplifies a case where the transistor TR is a top-gate transistor. However, this embodiment shall not be limited to such a case. The transistor TR may be a bottom-gate transistor.

Each of the gate electrode G, the source electrode S, and the drain electrode D can be, for example, a metal monolayer film containing at least one of aluminum, tungsten, molybdenum, tantalum, chromium, titanium, or copper. Alternatively, each electrode can be a metal multilayer film containing these metals.

Each of the inorganic insulating film 16, the inorganic insulating film 18, and the inorganic insulating film 20 can be, for example, a silicon oxide film, a silicon nitride film, or a silicon oxynitride film formed by the CVD. Alternatively, each of the inorganic insulating films 16, 18, and 20 can be a multilayer film including these films.

The planarization film 21 may be formed of, for example, an applicable organic material such as polyimide or acrylic. Alternatively, the planarization film 21 may be formed of an inorganic film.

The red light-emitting element 5R included in the red subpixel RSUB includes: a first electrode 22 provided above the planarization film 21; a functional layer 24R including a red light-emitting layer; and a second electrode 25. The green light-emitting element 5G included in the green subpixel GSUB includes: a first electrode 22 provided above the planarization film 21; a functional layer 24G including a green light-emitting layer; and the second electrode 25. The blue light-emitting element 5B included in the blue subpixel BSUB includes: a first electrode 22 provided above the planarization film 21; a functional layer 24B including a blue light-emitting layer; and the second electrode 25. Note that the bank 23, which is insulative and covers an edge of each first electrode 22, can be, for example, formed of such an organic material as polyimide or acrylic applied, and then patterned by photolithography. Alternatively, the bank 23 may be formed of an inorganic film.

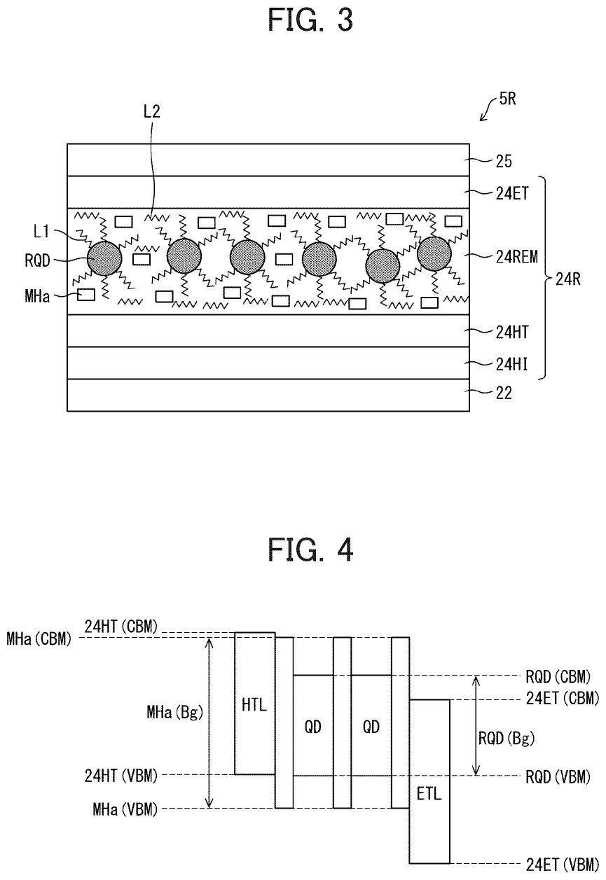

This embodiment exemplifies a case where each of the red light-emitting element 5R, the green light-emitting element 5G, and the blue light-emitting element 5B has a forward-order stack structure. However, this embodiment shall not be limited to such a case. Each of the red light-emitting element 5R, the green light-emitting element 5G, and the blue light-emitting element 5B may have a reverse-order stack structure. The red light-emitting element 5R (see FIG. 3) in the forward-order stack structure includes: the first electrode 22 serving as an anode; and the second electrode 25 provided above the first electrode 22 and serving as a cathode. The functional layer 24R, including a red light-emitting layer 24REM provided between the first electrode 22 serving as an anode and the second electrode 25 serving as a cathode, can be formed of, for example: a hole injection layer; a hole transport layer; the red light-emitting layer; an electron transport layer; and an electron injection layer, all of which are stacked on top of another in the stated order from toward the first electrode 22. The functional layer 24R including the red light-emitting layer 24REM may omit as appropriate one or more of the hole injection layer, the hole transport layer, the electron transport layer, and the electron injection layer, except for the red light-emitting layer 24REM. This embodiment exemplifies a case where the functional layer 24R including the red light-emitting layer 24REM includes: a hole injection layer HI; a hole transport layer 24HT; the red light-emitting layer 24REM; and an electron transport layer 24ET, all of which are stacked on top of another in the stated order from toward an anode serving as the first electrode 22. However, this embodiment shall not be limited to such a case. The green light-emitting element 5G in the forward-order stack structure includes: the first electrode 22 serving as an anode; and the second electrode 25 provided above the first electrode 22 and serving as a cathode. The functional layer 24G, including a green light-emitting layer provided between the first electrode 22 serving as an anode and the second electrode 25 serving as a cathode, can be formed of: a hole injection layer; a hole transport layer; the green light-emitting layer; an electron transport layer; and an electron injection layer, all of which are stacked on top of another in the stated order from toward the first electrode 22. The functional layer 24G including the green light-emitting layer may omit as appropriate one or more of the hole injection layer, the hole transport layer, the electron transport layer, and the electron injection layer, except for the green light-emitting layer. This embodiment exemplifies a case where the functional layer 24G including the green light-emitting layer includes: a hole injection layer; a hole transport layer; the green light-emitting layer; and an electron transport layer, all of which are stacked on top of another in the stated order from toward an anode serving as the first electrode 22. However, this embodiment shall not be limited to such a case. The blue light-emitting element 5B in the forward-order stack structure includes: the first electrode 22 serving as an anode; and the second electrode 25 provided above the first electrode 22 and serving as a cathode. The functional layer 24B, including a blue light-emitting layer provided between the first electrode 22 serving as an anode and the second electrode 25 serving as a cathode, can be formed of, for example: a hole injection layer; a hole transport layer; the blue light-emitting layer; an electron transport layer; and an electron injection layer, all of which are stacked on top of another in the stated order from toward the first electrode 22. The functional layer 24B including the blue light-emitting layer may omit as appropriate one or more of the hole injection layer, the hole transport layer, the electron transport layer, and the electron injection layer, except for the blue light-emitting layer. This embodiment exemplifies a case where the functional layer 24B including the blue light-emitting layer includes: a hole injection layer; a hole transport layer; the blue light-emitting layer; and an electron transport layer, all of which are stacked on top of another in the stated order from toward an anode serving as the first electrode 22. However, this embodiment shall not be limited to such a case.

A red light-emitting element 5R′ (see FIG. 8) in the reverse-order stack structure includes: the first electrode 22 serving as a cathode; and the second electrode 25 provided above the first electrode 22 and serving as an anode. A functional layer 24R′, including the red light-emitting layer 24REM provided between the first electrode 22 serving as a cathode and the second electrode 25 serving as an anode, can be formed of, for example: an electron injection layer; an electron transport layer; a red light-emitting layer; a hole transport layer; and a hole injection layer, all of which are stacked on top of another in the stated order from toward the first electrode 22. The functional layer 24R′ including the red light-emitting layer 24REM may omit as appropriate one or more of the electron injection layer, the electron transport layer, the hole transport layer, and the hole injection layer, except for the red light-emitting layer 24REM. Although not shown, a green light-emitting element in the reverse-order stack structure includes: a first electrode serving as a cathode; and a second electrode provided above the first electrode and serving as an anode. A functional layer, including a green light-emitting layer provided between the first electrode serving as a cathode and the second electrode serving as an anode, can be formed of: an electron injection layer; an electron transport layer; the green light-emitting layer; a hole transport layer; and a hole injection layer, all of which are stacked on top of another in the stated order from toward the first electrode. The functional layer including the green light-emitting layer may omit as appropriate one or more of the electron injection layer, the electron transport layer, the hole transport layer, and the hole injection layer, except for the green light-emitting layer. Although not shown, a blue light-emitting element in the reverse-order stack structure includes: a first electrode serving as a cathode; and a second electrode provided above the first electrode and serving as an anode. A functional layer, including a blue light-emitting layer provided between the first electrode serving as a cathode and the second electrode serving as an anode, can be formed of, for example: an electron injection layer; an electron transport layer; the blue light-emitting layer; a hole transport layer; and a hole injection layer, all of which are stacked on top of another in the stated order from toward the first electrode. The functional layer including the blue light-emitting layer may omit as appropriate one or more of the electron injection layer, the electron transport layer, the hole transport layer, and the hole injection layer, except for the blue light-emitting layer.

The hole injection layer may be formed of any given material as long as the material is a hole injection material capable of stably injecting the holes into the light-emitting layer. The hole injection material may be, for example, PEDOT: PSS.

Examples of the material to be used for the hole transport layer may include an organic material such as: poly[(9,9-dioctylfluorenyl-2,7-diyl)-co-(4,4′-(N-(4-sec-butylphenyl))diphenylamine)] (TFB); N,N′-bis(4-butylphenyl)-N,N′-bis(phenyl)-benzidine (poly-TPD); or polyvinylcarbazole (PVK). Alternatively, the material may be nanoparticles such as NiO particles capable of transporting holes.

Examples of the material to be used for the electron transport layer may include an organic material such as 2,2′,2″-(1,3,5,-benzinetriyl)-tris(1-phenyl-1-H-benzimidazole) (TPBi). Alternatively, the material may be nanoparticles such as ZnO particles capable of transporting electrons.

The material to be used for the electron injection layer may be any given electron injecting material as long as the material is capable of stably injecting the electrons in the light-emitting layer. Examples of the electron injecting material may include: alkali metals or alkali earth metals such as aluminum, strontium, calcium, lithium, cesium, magnesium oxide, aluminum oxide, strontium oxide, lithium oxide, lithium fluoride, magnesium fluoride, strontium fluoride, calcium fluoride, barium fluoride, cesium fluoride, sodium polymethylmethacrylate polystyrene sulfonate; oxides of alkali metals or alkali earth metals; fluorides of alkali metals or alkali earth metals; and organic complexes of alkali metals.

This embodiment exemplifies a case where the functional layer 24R including the red light-emitting layer, the functional layer 24G including the green light-emitting layer, and the functional layer 24B including the blue light-emitting layer include: hole injection layers formed of the same material at the same step, hole transport layers formed of the same material at the same step; and electron transport layer formed of the same material at the same step. However, this embodiment shall not be limited to such a case. For example, the hole injection layers included in the respective functional layers 24R, 24G, and 24B may be formed of materials different from one another. Alternatively, the hole injection layers included in two of the functional layers 24R, 24G, and 24B may be formed of the same material at the same step, and the hole injection layer included in the remaining one functional layer alone may be formed of a different material at a separate step. Furthermore, for example, the hole transport layers included in the respective functional layers 24R, 24G, and 24B may be formed of materials different from one another. Alternatively, the hole transport layers included in two of the functional layers 24R, 24G, and 24B may be formed of the same material at the same step, and the hole transport layer included in the remaining one functional layer alone may be formed of a different material at a separate step. Moreover, for example, the electron transport layers included in the functional layers 24R, 24G, and 24B may be formed of materials different from one another. Alternatively, the electron transport layers included in two of the functional layers 24R, 24G, and 24B may be formed of the same material at the same step, and the electron transport layer included in the remaining one functional layer alone may be formed of a different material at a separate step.

This embodiment exemplifies a case where any of the red light-emitting element 5R, the green light-emitting element 5G, and the blue light-emitting element 5B is a quantum-dot light-emitting diode (QLED). However, this embodiment shall not be limited to such a case. One or more of the red light-emitting element 5R, the green light-emitting element 5G, and the blue light-emitting element 5B may be QLEDs. For example, if one of the red light-emitting element 5R, the green light-emitting element 5G, or the blue light-emitting element 5B is a QLED, the remaining two light-emitting elements may be organic light-emitting diodes (OLEDs). For example, if two of the red light-emitting element 5R, the green light-emitting element 5G, and the blue light-emitting element 5B are QLEDs, the remaining one light-emitting element may be an OLED.

As seen in this embodiment, if each of the red light-emitting element 5R, the green light-emitting element 5G, and the blue light-emitting element 5B is a QLED, the light-emitting layer included in the light-emitting element in each color contains quantum dots. The quantum dots may have, for example, a core-shell structure, a core-shell-core structure, and a shell structure whose core-ratio varies continuously. Note that the shell may cover the core either completely or partially. The core can be formed of, for example: Si or C in a case of a simple substance; CdSe, CdS, CdTe, InP, GaP, InN, ZnSe, ZnS, or ZnTe in a case of a binary compound; CdSeTe, GaInP, or ZnSeTe in a case of a ternary compound; and AIGS in a case of a quaternary compound. The shell can be formed of, for example: CdS, CdTe, CdSe, ZnS, ZnSe, or ZnTe in a case of a binary compound; and CdSSe, CdTeSe, CdSTe, ZnSSe, ZnSTe, ZnTeSe, or AIP in a case of a ternary compound.

Here, the quantum dots are those including either organic ligands or inorganic ligands (e.g., halogen ligands) disposed either on or near the surface of the quantum dots.

Note that a maximum width of each of the quantum dots excluding the ligands is narrower than, or equal to, 100 nm. Furthermore, each of the quantum dots may have any given shape except for the ligands, as long as the maximum width of the quantum dot is within the above range. The shape of the quantum dot shall not be limited to a spherical shape (a circular cross-section). For example, the quantum dot may have a polygonal cross-section, a bar-like three dimensional shape, a branch-like three dimensional shape, or a three dimensional shape having asperities on the surface. Alternatively, the quantum dot may have a combination of those shapes.

Each of the red light-emitting element 5R, the green light-emitting element 5G, and the blue light-emitting element 5B is controlled by the respective transistors TR included in the respective control circuits. The control circuits are provided to the thin-film transistor layer 4 including the transistors TR for the respective red subpixel RSUB, green subpixel GSUB, and blue subpixel BSUB. Note that a light-emitting element and a control circuit, which includes a transistor TR provided for each of the red subpixel RSUB, the green subpixel GSUB, and the blue subpixel BSUB, are collectively referred to as a subpixel circuit.

The red light-emitting element 5R, the green light-emitting element 5G, and the blue light-emitting element 5B illustrated in FIG. 2 may be either top-emission light-emitting elements or bottom-emission light-emitting elements. Each of the red light-emitting element 5R, the green light-emitting element 5G, and the blue light-emitting element 5B has the forward-order stack structure in which the second electrode 25 serving as a cathode is provided above the first electrode 22 serving as an anode. Hence, if each light-emitting element is to be formed as a top-emission light-emitting element, the first electrode 22 serving as an anode may be formed of an electrode material reflective to visible light, and the second electrode 25 serving as a cathode may be formed of an electrode material transparent to visible light. If each light-emitting element is to be formed as a bottom-emission light-emitting element, the first electrode 22 serving as an anode may be formed of an electrode material transparent to visible light, and the second electrode 25 serving as a cathode may be formed of an electrode material reflective to visible light. Whereas, suppose if each of the red light-emitting element 5R′ (see FIG. 8), the green light-emitting element, and the blue light-emitting element has the reverse-order stack structure in which the second electrode 25 serving as an anode is provided above the first electrode 22 serving as a cathode. If each light-emitting element is to be formed as a top-emission light-emitting element, the first electrode 22 serving as a cathode may be formed of an electrode material reflective to visible light, and the second electrode 25 serving as an anode may be formed of an electrode material transparent to visible light. If each light-emitting element is to be formed as a bottom-emission light-emitting element, the first electrode 22 serving as a cathode may be formed of an electrode material transparent to visible light, and the second electrode 25 serving as an anode may be formed of an electrode material reflective to visible light.

The electrode material reflective to visible light may be any given material as long as the material can reflect visible light and conduct electricity. Examples of the electrode material include: a metal material such as Al, Mg, Li, or Ag; an alloy of the metal materials; a multilayer stack of the metal material and a transparent metal oxide (e.g., indium tin oxide, indium zinc oxide, or indium gallium zinc oxide); or a multilayer stack of the alloy and the transparent metal oxide.

Whereas, the electrode material transparent to visible light may be any given material as long as the material can transmit visible light and conduct electricity. Examples of the electrode material include: a transparent metal oxide (e.g., indium tin oxide, indium zinc oxide, or indium gallium zinc oxide); a thin film formed of a metal material such as Al or Ag; or nano wires formed of a metal material such as Al or Ag.

The first electrode 22 and the second electrode 25 can be deposited by a typical technique to form an electrode. Examples of the technique include: physical vapor deposition (PVD) such as vacuum evaporation, sputtering, EB evaporation, and ion plating; or chemical vapor deposition (CVD). Furthermore, the first electrode 22 and the second electrode 25 may be patterned by any given technique as long as these electrodes are formed precisely in desired patterns. Examples of the technique specifically include photolithography and inkjet printing.

The sealing layer 6 is a light-transparent film. The sealing layer 6 includes, for example: an inorganic sealing film 26 covering a second electrode 25; an organic film 27 above the inorganic sealing film 26; and an inorganic sealing film 28 above the organic film 27. The sealing layer 6 prevents foreign substances such as water and oxygen from penetrating into the red light-emitting element 5R, the green light-emitting element 5G, and the blue light-emitting element 5B.

Each of the inorganic sealing film 26 and the inorganic sealing film 28 is an inorganic film. For example, the inorganic film can be a silicon oxide film, a silicon nitride film, or a silicon oxynitride film formed by the CVD. Alternatively, the inorganic film can be a multilayer film including these films. The organic film 27 is a light-transparent organic film exhibiting a planarizing effect. The organic film 27 can be made of, for example, an applicable organic material such as acrylic. The organic film 27 may be formed by, for example, inkjet printing. This embodiment exemplifies a case where the sealing layer 6 is formed of two inorganic films and one organic film provided between the two inorganic films. However, this embodiment shall not be limited to such a case. Furthermore, the sealing layer 6 may be formed of an inorganic film alone, may be formed of one inorganic film and two organic films, or may be formed of two or more inorganic films and two or more organic films.

The functional film 39 has at least one of, for example, an adaptive optics correction function, a touch sensor function, or a protection function.

FIG. 3 is a cross-sectional view of a schematic configuration of the red light-emitting element 5R included in the display device 1 according to the first embodiment. The red light-emitting element 5R illustrated in FIG. 3 is in an initial state in which the red light-emitting element 5R is either before driven or driven for a relatively short time.

As illustrated in FIG. 3, the functional layer 24R, including the red light-emitting layer 24REM provided between the first electrodes 22 serving as an anode and the second electrode 25 serving as a cathode, can be formed of: the hole injection layer 24HI; the hole transport layer 24HT; the red light-emitting layer 24REM; and the electron transport layer 24ET, all of which are stacked on top of another in the stated order from toward the first electrode 22.

The red light-emitting layer 24REM contains: red light-emitting quantum dots RQD containing ligands L1; ligands L2; and a metal halide MHa.

This embodiment exemplifies a case where organic ligands are used as ligands that terminate surface defects found on the surface of the red light-emitting quantum dots RQD. However, this embodiment shall not be limited to such a case. For example, the ligands to be used may be halogen ligands. The ligands L1 illustrated in FIG. 3 are ligands disposed either on or near the surface of the red light-emitting quantum dots RQD. The ligands L2 illustrated in FIG. 3 are extra ligands positioned slightly away from the surface of the red light-emitting quantum dots RQD. The ligands L2 compensate for the ligands L1.

This embodiment exemplifies a case where the ligands L1 and the ligands L2 are trioctylphosphine (TOP); that is, organic ligands having a melting point of 30° C. and a boiling point of 234° C. However, this embodiment shall not be limited to such a case. The ligands L1 and the ligands L2 may be organic ligands having a melting point of 50° C. or below. For example, the ligands L1 and the ligands L2 may be either: oleic acid (OA) that is organic ligands having a melting point of 13° C. and a boiling point of 360° C.; or dodecanethiol (DDT) that is organic ligands having a melting point of −7° C. and a boiling point of 277° C.

This embodiment exemplifies a case where one kind of organic ligands are used as the ligands L1 and the ligands L2. However, this embodiment shall not be limited to such a case, and two or more kinds of organic ligands may be used. For example, two or more of trioctylphosphine (TOP), oleic acid (OA), and dodecanethiol (DDT) can be used as the ligands L1 and the ligands L2.

FIG. 6 is a graph showing a relationship between: the current density of a current flowing between the first electrode 22 and the second electrode 25 provided to each of the plurality of light-emitting elements 5R, 5G, and 5B of the display device 1 according to the first embodiment; and the temperature of the light-emitting elements 5R, 5G, and 5B.

As illustrated in FIG. 6, under a normal light-emitting-element drive condition (at a drive voltage of, for example, 5 V) in which a current, flowing between the first electrode 22 and the second electrode 25 included in each of the plurality of light-emitting elements 5R, 5G, and 5B of the display device 1, has a current density of, for example, approximately 10mA/cm², the temperature of the light emitting elements 5R, 5G, and 5B each including the light-emitting layer rises to approximately 50° C.

As described above, in this embodiment, the ligands L1 and the ligands L2 are trioctylphosphine (TOP) having a melting point of 30° C. Hence, under the above normal light-emitting-element drive condition in which the temperature of the light-emitting elements 5R, 5G, and 5B each including the light-emitting layer rises to approximately 50° C., the ligands L1 and the ligands L2 are found in a liquid state in the light-emitting layer. Thus, the ligands L1 and the ligands L2 found in the form of a liquid; in particular, the ligands L2 positioned slightly away from the surface of the quantum dots, are highly volatile.

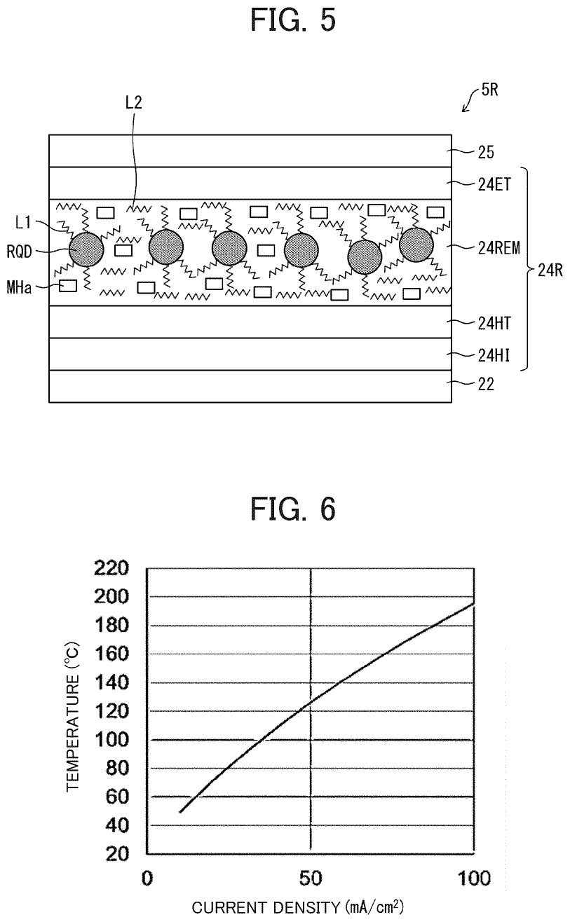

FIG. 5 is a diagram showing how the red light-emitting layer 24REM changes over time after the red light-emitting element 5R illustrated in FIG. 3 has been driven for a predetermined time period.

Compared with the red light-emitting layer 24REM included in the red light-emitting element 5R in the initial state in FIG. 3, the red light-emitting layer 24REM included in the red light-emitting element 5R after driven for the predetermined time period illustrated in FIG. 5 shows that the ligands L1 disposed either on or near the surface of the red light-emitting quantum dots RQD are desorbed with the passage of time and the stress of drive by a current. The desorption results in a decrease in the number of the ligands L1 per one red light-emitting quantum dot RQD. Originally, the ligands L2 play a role of compensating for the ligands L1 desorbed from the surface of, or near the surface of, the red light-emitting quantum dots RQD. However, as described above, the ligands L2 are found in a liquid state in the light-emitting layer under the normal light-emitting-element drive condition. Hence, the ligands L2 illustrated in FIG. 5 gradually vaporizes with the passage of time, and that is why the extra ligands L2 for compensating for the desorbed ligands L1 run short. Hence, the red light-emitting quantum dots RQD are deactivated because of the surface defects. The deactivation makes it difficult to ensure the long-term reliability of the red light-emitting element 5R. The deactivation also makes it impossible to avoid a decrease in emission characteristic (light emission efficiency) of the red light-emitting layer 24 REM containing the red light-emitting quantum dots RQD, which occurs with the passage of time. Allowing for the amount of the ligands L2 gradually vaporizing with the passage of time, the ligands L2; that is, extra ligands for compensating for the ligands L1, could be originally contained in large amount in the red light-emitting layer 24REM. However, for example, trioctylphosphine (TOP), oleic acid (OA), and dodecanethiol (DDT), which are organic ligands and used as the ligands L1 and the ligands L2, are insulative. If these substances are contained in large amount in the red light-emitting layer 24REM, it would be difficult to inject the holes from the hole transport layer 24HT and to inject the electrons from the electron transport layer 24ET. As a result, the red light-emitting element 5R inevitably suffers a rise in drive voltage and a deterioration in electric characteristic. For these reasons, the amount of the ligands L2 contained in the red light-emitting layer 24 REM is preferably determined as appropriate within a range in which characteristics can be maintained well for injecting the holes from the hole transport layer 24HT and the electrons from the electron transport layer 24ET.

Note that if the ligands L1 and the ligands L2 are, for example, either oleic acid (OA) having a melting point of 13° C. or dodecanethiol (DDT) having a melting point of −7° C., the ligands L1 and the ligands L2 are found in a liquid state in the light-emitting layer not only under the normal light-emitting-element drive condition described above but also under an undriven condition of the light-emitting element; that is, for example, when the light-emitting element is stored at a room temperature of 25° C. Hence, the ligands L2 evaporate in larger amount, making it difficult to ensure the long-term reliability of the light-emitting element, and making it impossible to avoid a decrease, with the passage of time, in emission characteristic (light emission efficiency) of the light-emitting layer containing the quantum dots.

In this embodiment, as illustrated in FIG. 3, the red light-emitting layer 24REM included in the red light-emitting element 5R contains: the red light-emitting quantum dots RQD containing the ligands L1; the ligands L2; and the metal halide MHa. That is, the red light-emitting layer 24REM is a layer in which the red light-emitting quantum dots RQD containing ligands L1, the ligands L2, and the metal halide MHa are mixed together.

This embodiment exemplifies a case where the red light-emitting layer 24REM contains the ligands L2. However, this embodiment shall not be limited to such a case. The red light-emitting layer 24REM may omit the ligands L2, and may contain the red light-emitting quantum dots RQD containing the ligands L1 and the metal halide MHa.

FIG. 4 is a diagram illustrating band levels of the hole transport layer 24HT, the electron transport layer 24ET, the red light-emitting quantum dots RQD containing the ligands L1, and the metal halide MHa, all of which are included in the red light-emitting element 5R illustrated in FIG. 3.

As illustrated in FIG. 4, regarding the metal halide MHa to be preferably used, a bandgap of the metal halide MHa (MHa (Bg)) representing a difference between a valence band maximum of the metal halide MHa (MHa (VBM)) and a conduction band minimum of the metal halide MHa (MHa (CBM)) is larger than, or equal to, a bandgap of the red light-emitting quantum dots RQD (RQD (Bg)) representing a difference between a valence band maximum of the red light-emitting quantum dots RQD (RQD (VBM)) and a conduction band minimum of the red light-emitting quantum dots RQD (RQD (CBM)). This embodiment exemplifies a case where the valence band maximum of the metal halide MHa (MHa (VBM)) is deeper than the valence band maximum of the red light-emitting quantum dots RQD (RQD (VBM)), and where the conduction band minimum of the metal halide MHa (MHa (CBM)) is shallower than the conduction band minimum of the red light-emitting quantum dots RQD (RQD (CBM)). However, this embodiment shall not be limited to such a case.

As can be seen, the metal halide MHa to be used has a bandgap larger than the bandgap of the red light-emitting quantum dots RQD (RQD (Bg)). Such a feature can reduce current leakage that could occur among the plurality of light-emitting elements through the metal halide MHa. This embodiment exemplifies a case where the red light-emitting quantum dots RQD to be used has a valence band maximum (RQD (VBM)) of −5.6 eV, a conduction band minimum (RQD (CBM)) of −3.6 eV, and a bandgap (RQD (Bg)) of 2 eV. However, this embodiment shall not be limited to such a case.

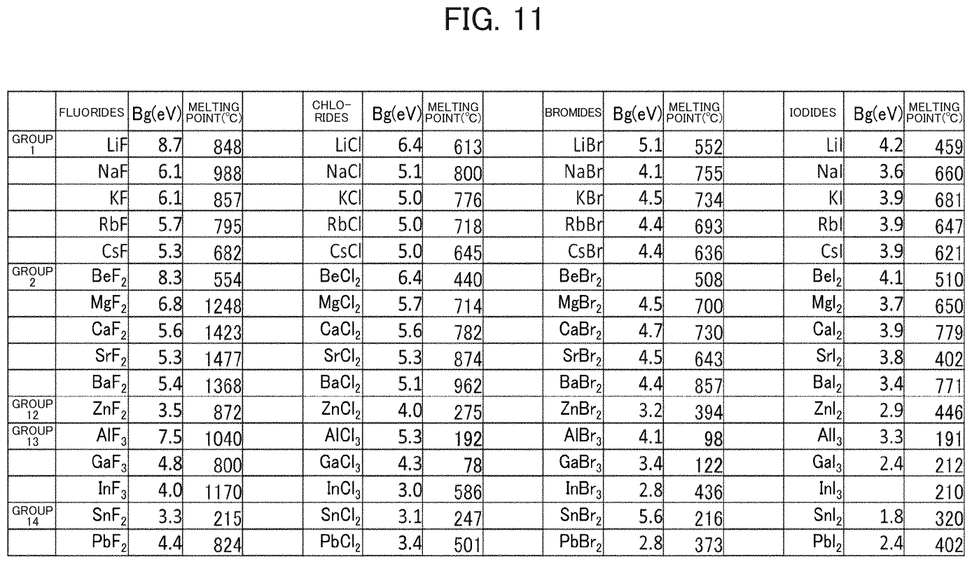

FIG. 11 illustrates an example of materials that can be used as the metal halide MHa to be contained in the light-emitting layer of each of the light-emitting elements 5R, 5G and 5B in the respective colors, included in the display device 1 according to the first embodiment.

In order to reduce the current leakage that could occur among the plurality of light-emitting elements through the metal halide MHa described above, the metal halide MHa contained in the red light-emitting layer 24REM included in the red light-emitting element 5R is preferably a metal halide MHa: having a bandgap (MHa (Ba)) larger than, or equal to, the bandgap of the red light-emitting quantum dots RQD (e.g., RQD (Bg)=2 eV); and selected from the fluorides, the chlorides, the bromides, and the iodides of various kinds of metal halides shown in FIG. 11.

The metal halide MHa contained in the red light-emitting layer 24REM included in the red light-emitting element 5R of this embodiment is more preferably a metal halide: selected from, for example, the various kinds of metal halides shown in FIG. 11; and having a bandgap (MHa (Ba)) larger than, or equal to, the bandgap of the red light-emitting quantum dots RQD (e.g., RQD (Bg) −2 eV), wherein the bandgap of the metal halide MHa is smaller than a value (e.g., 6 eV) three times as large as the bandgap of the red light-emitting quantum dots RQD (e.g., RQD (Bg)=2 eV). As can be seen, the bandgap of the halide MHa (MHa (Bg)) is set smaller than a value three times as large as the bandgap of the red light-emitting quantum dots RQD (RQD (Bg)). Such a feature can reduce a deterioration in electric characteristic of the red light-emitting element 5R.

In a case of using the metal halide MHa having a bandgap larger than the bandgap of the red light-emitting quantum dots ROD (RQD (Bg)), the amount of the metal halide MHa contained in the red light-emitting layer 24 REM is preferably determined as appropriate within a range in which characteristics can be maintained well for injecting the holes from the hole transport layer 24HT and the electrons from the electron transport layer 24ET.

Furthermore, a step temperature of a step of melting the metal halide MHa to be described later is preferably a temperature that does not thermally damage the hole injection layer 24HI, the hole transport layer 24HT, the ligands L1 and L2 contained in the red light-emitting layer 24 REM, and the electron transport layer 24ET illustrated in FIGS. 3 and 5.

For example, if each of the hole injection layer 24HI, the hole transport layer 24HT, the ligands L1 and L2 contained in the red light-emitting layer 24 REM, and the electron transport layer 24ET illustrated in FIGS. 3 and 5 is an organic material, a step temperature of the step of melting the metal halide MHa is preferably 200° C. or below not to thermally damage these organic materials. In order to set the step temperature of the step of melting the metal halide MHa to 200° C. or below, a metal halide MHa having a melting point of 200° C. or below may be selected from the fluorides, the chlorides, the bromides, and the iodides of various kinds of metal halides shown in FIG. 11. Examples of the metal halide MHa contained in the red light-emitting layer 24REM and having a melting point of 200° C. preferably include GaCl₃ having a melting point of 78° C., AlBr₃ having a melting point of 98° C., GaBr₃ having a melting point of 122° C., AlI₃ having a melting point of 191° C., and AlCl₃ having a melting point of 192° C.

Examples of the metal halide MHa to be contained in the red light-emitting layer 24REM included in the red light-emitting element 5R of this embodiment preferably include: GaGl₃ having a melting point of 78° C. and a bandgap Bg of 4.3 eV; AIBr₃ having a melting point of 98° C. and a bandgap Bg of 4.1 eV; GaBr₃ having a melting point of 122° C. and a bandgap Bg of 3.4 eV; AlI₃ having a melting point of 191° C. and a bandgap Bg of 3.3 eV; and AlCl₃ having a melting point of 192° C. and a bandgap Bg of 5.3 eV. These metal halides MHa have a bandgap larger than, or equal to, a bandgap of the red light-emitting quantum dots RQD (e.g., RQD (Bg)=2 eV), and can be melted at a step temperature of 200° C. or below at the step of melting the metal halide MHa so that the metal halides MHa are applicable if each of the hole injection layer 24HI, the hole transport layer 24HT, the ligands L1 and L2 contained in the red light-emitting layer 24REM, and the electron transport layer 24ET is an organic material.

Furthermore, if the red light-emitting quantum dots RQD each have a core and a shell, and the shell is formed of cubic ZnS (having a bandgap Bg of 3.4 eV), a metal halide having a bandgap Bg of 3.4 eV or larger and 5.3 eV or smaller is preferably selected from the various metal halides shown in FIG. 11. Examples of the metal halide preferably include: GaGl₃ having a melting point of 78° C. and a bandgap Bg of 4.3 eV; AIBr₃ having a melting point of 98° C. and a bandgap Bg of 4.1 eV; GaBr₃ having a melting point of 122° C. and a bandgap Bg of 3.4 eV; and AlCl₃ having a melting point of 192° C. and a bandgap Bg of 5.3 eV. As can be seen, if a bandgap of the metal halide MHa (MHa (Bg)) is 3.4 eV or larger and 5.3 eV or smaller, the bandgap is close to a bandgap Bg of the cubic ZnS (3.4 eV) forming the shells of the red light-emitting quantum dots RQD. Such a feature can reduce a deterioration in electric characteristic of the red light-emitting element 5R to a minimum.

This embodiment exemplifies a case where the metal halide MHa contained in the red light-emitting layer 24REM is GaCl₃ having a melting point of 78° C. and a bandgap Bg of 4.3 eV. However, this embodiment shall not be limited to such a case.

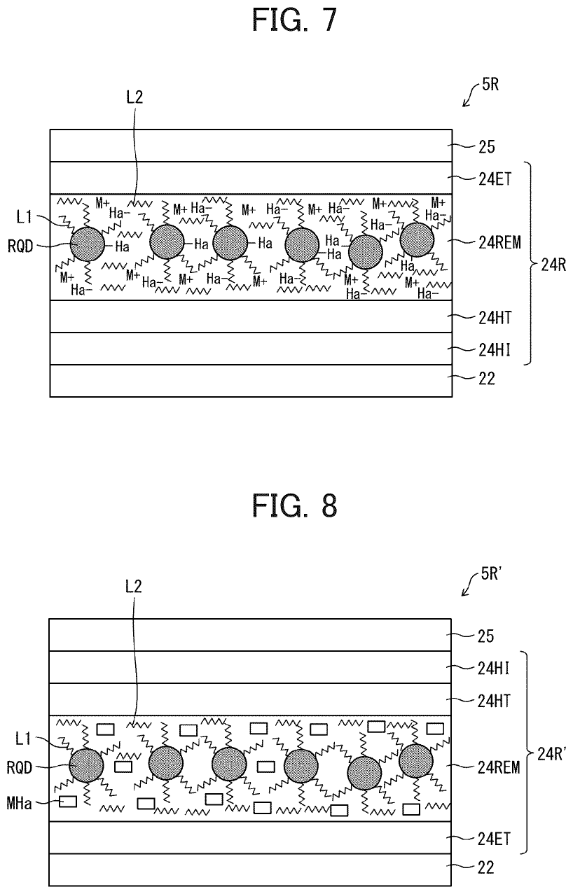

FIG. 7 is a diagram showing, as to the red light-emitting layer 24REM of the red light-emitting element 5R illustrated in FIG. 5 and changed over time, how the metal halide MHa contained in the red light-emitting layer 24REM is melted and an emission characteristic (light emission efficiency) of the red light-emitting element 5R is restored.

The melting point of the metal halide MHa contained in the red light-emitting layer 24REM is preferably higher than 50° C. In such a case, the metal halide MHa contained in the red light-emitting layer 24REM is found in a solid state under the normal light-emitting-element drive condition in which the temperature of the light-emitting elements 5R, 5G, and 5B each including the light-emitting layer rises to approximately 50° C., and under the undriven condition of the light-emitting element; that is, for example, when the light-emitting element is stored at a room temperature of 25° C. Here, a vapor pressure of the metal halide MHa is infinitely low, and the evaporation of the metal halide MHa contained in the red light-emitting layer 24REM can be ignored. Because of such a reason, in this embodiment, GaCl₃ having a melting point of 78° C. and a bandgap Bf of 4.3 eV is used as the metal halide MHa to be contained in the red light-emitting layer 24REM.

Whereas, the red light-emitting layer 24REM included in the red light-emitting element 5R after driven for the predetermined time period illustrated in FIG. 7 shows that the ligands L1 disposed either on or near the surface of the red light-emitting quantum dots RQD are desorbed with the passage of time and the stress of drive by a current. The desorption results in a decrease in the number of the ligands LI per one red light-emitting quantum dot RQD. Furthermore, the ligands L2 are found in a liquid state in the light-emitting layer under the normal light-emitting-element drive condition. Hence, the ligands L2 gradually vaporizes with the passage of time, and that is why the extra ligands L2 for compensating for the desorbed ligands L1 run short. Hence, the red light-emitting quantum dots RQD are deactivated because of the surface defects. The deactivation makes it difficult to ensure the long-term reliability of the red light-emitting element 5R. The deactivation also makes it impossible to avoid a decrease in emission characteristic (light emission efficiency) of the red light-emitting layer 24 REM containing the red light-emitting quantum dots RQD, which occurs with the passage of time.

Hence, as illustrated in FIG. 7, a step is carried out to melt the metal halide MHa contained in the red light-emitting layer 24REM included in the red light-emitting element 5R driven for a predetermined time period. That is, a method including the step of melting the metal halide MHa is carried out to restore an emission characteristic (light emission efficiency) of the red light-emitting element 5R. If the metal halide MHa is left in a solid state, metal ions M+ and halogen ions Ha− forming the metal halide MHa do not move much. Hence, the halogen ions Ha− do not have much chance to meet the surface defects, of the red light-emitting quantum dots RQD, caused by desorption of the ligands L1, or to terminate the surface defects of the red light-emitting quantum dots RQD. Because of such reasons, the step of melting the metal halide MHa contained in the red light-emitting layer 24REM is temporality carried out to melt and ionize the metal halide MHa. As a result, the halogen ions Ha-exhibit an increase in movement and terminate the surface defects of the red light-emitting quantum dots RQD.

Furthermore, the step of melting the metal halide MHa contained in the red light-emitting layer 24REM is carried out, so that the ligands L2 contained in the red light-emitting layer 24REM are brought to a liquid state. Hence, the metal ions M+ and the halogen ions Ha-forming the metal halide MHa move in the liquid, thereby making it possible to further increase a chance of terminating the surface defects of the red light-emitting quantum dots RQD.

Moreover, if the ligands L1 and the ligands L2 are, for example, oleylamine; that is, organic ligands having a melting point of 50° C., and the temperature of the red light-emitting layer 24REM is raised to melt the oleylamine, the metal halide MHa can be dissolved (melted) in the oleylamine in a liquid state. Hence, the metal ions M+ and the halogen ligands Ha-forming the metal halide MHa move in the liquid. Such a feature makes it possible to further increase a chance of terminating the surface defects of the red light-emitting quantum dots RQD. Furthermore, the metal halide MHa can be dissolved in the oleylamine in a liquid state without raising the temperature of the red light-emitting layer 24REM to a temperature at which the metal halide MHa melts.

In this embodiment, the metal halide MHa is GaCl₃ having a melting point of 78° C. and a bandgap Bg of 4.3 eV. Such a feature allows the metal halide MHa; namely GaCl₃, to melt at a relatively low temperature of 78° C. Thus, at the step of melting the metal halide MHa, thermal damage is not inflicted on the hole injection layer 24HI, the hole transport layer 24HT, the ligands L1 and L2 contained in the red light-emitting layer 24 REM, and the electron transport layer 24ET illustrated in FIG. 7.

At the step of melting the metal halide MHa, the metal halide MHa in a liquid state is ionized into the metal ions M+ and the halogen ions Ha−. In this embodiment, the metal ions M+ are Ga₃+ and the halogen ions Ha− are Cl−.

Note that the metal halide MHa contained in the red light-emitting layer 24REM may contain, for example, two or more different kinds of metal halides selected from GaCl₃, AlBr₃, GaBr₃, AlI₃, and AlCl₃ among the various kinds of metal halides shown in FIG. 11. As can be seen, a mixture of two or more kinds of metal halides can melt at a lower temperature because of a fall of the freezing point.

As illustrated in FIG. 6, under a drive condition (at a drive voltage of, for example, 5 V) in which a current, flowing between the first electrode 22 and the second electrode 25 included in each of the plurality of light-emitting elements 5R, 5G, and 5B of the display device 1, has a current density of, for example, approximately 100 mA/cm², the temperature of the light emitting elements 5R, 5G, and 5B each including the light-emitting layer rises to approximately 200° C.

The scan drive circuit 31 and the data drive circuit 32 included in the display device 1 of this embodiment illustrated in FIG. 1 have a mode for performing a step of melting the metal halide MHa.

In accordance with a video signal input from outside, the data drive circuit 32: supplies a current, between the first electrode 22 and the second electrode 25 included in each of the plurality of the light-emitting elements 5R, 5G, and 5B, at a current density selected within a first current density range; and causes the light-emitting layer included in each of the plurality of light-emitting elements 5R, 5G, and 5B to emit light at a luminance corresponding to the selected current density. The melting point of the metal halide MHa is higher than the temperature observed of the plurality of light-emitting elements 5R, 5G, 5B when the current is supplied between the first electrodes 22 and the second electrodes 25 at the selected current density.

In this embodiment, GaCl₃ having a melting point of 78° C. and a bandgap Bg of 4.3 eV is used as the metal halides MHa, MHa′, and MHa″ contained in the respective light-emitting layers 24 in the respective colors. Hence, because of the relationship between the current density and the temperature of the light-emitting elements 5R, 5G, and 5B illustrated in FIG. 6, the first current density range has to be set to have a highest temperature of below 78° C. Thus, for the data drive circuit 32, the first current density range is set to, for example, 0 mA/cm² or higher and 20 mA/cm² or lower, and the maximum temperature of the light-emitting elements 5R, 5G, and 5B is set to 70° C. or below in the first current density range; that is, a drive condition (at a drive voltage of, for example, 5V) of the light-emitting elements for performing normal display in the display device 1. Hence, under the drive condition of the light-emitting elements for performing normal display in the display device 1, the metal halides MHa, MHa′, and MHa″ contained in the light-emitting layers 24 in the respective colors are found in a solid state, and the vapor pressure is lower in the solid state than that in a liquid state. As a result, the vaporization can be reduced.

The data drive circuit 32 included in the display device 1 of this embodiment illustrated in FIG. 1 further has a mode for performing a step of melting the metal halides MHa, MHa′, and MHa″. In the mode, the data drive circuit 32: supplies a current, between the first electrode 22 and second electrode 25 included in each of the light-emitting elements 5R, 5G, and 5B, at a current density selected in a second current density range having a value larger than a value of the first current density range; and raises the temperature of the plurality of light-emitting elements 5R, 5G, and 5B higher than the melting points of the metal halides MHa, MHa′, and MHa″.

In this embodiment, GaCl₃ having a melting point of 78° C. and a bandgap Bg of 4.3 eV is used as the metal halides MHa, MHa′, and MHa″ contained in the light-emitting layers in the respective colors. Hence, because of the relationship between the current density and the temperature of the light-emitting elements 5R, 5G, and 5B illustrated in FIG. 6, the second current density range has to be set to have a lowest temperature of 78° C. or above. Thus, for the data drive circuit 32, the second current density range is set to, for example, 30 mA/cm² or higher and 10 mA/cm² or lower. Hence, when the data drive circuit 32 included in the display device 1 is driven in the mode for performing the step of melting the metal halides MHa, MHa′, and MHa″; that is, when a current flows at a current density of 30 mA/cm² or higher between the first electrode 22 and second electrode 25 included in each of the plurality of light-emitting elements 5R, 5G, and 5B, the metal halides MHa, MHa′, and MHa″ contained in the light-emitting layers in the respective colors can be melted and ionized.

Note that the setting of the first current density range and the second current density range described above is an example, and shall not be limited to such an example. The first current density range and the second current density range may be set as appropriate in consideration of the melting points of the metal halides MHa, MHa′, and MHa″ to be used.

The above mode for performing the step of melting the metal halides MHa, MHa′, and MHa″ may be performed once or multiple times during a step of producing the display device 1 or after a user of the display device 1 starts using the display device 1.

As can be seen, this embodiment exemplifies a case where the step of melting the metal halides MHa, MHa′, and MHa″ are separately carried out. However, this embodiment shall not be limited to such a case. For example, the temperature of the light-emitting layer of each of the light-emitting elements in the respective colors included in the display device could rise even if a leakage path is formed in the light-emitting layer and a large amount of current locally flows in the leakage path. If silver widely used as a cathode of the light-emitting element and indium in ITO widely used as an anode of the light-emitting element are contained as electrode materials, metals such as silver and indium are reported to disperse and reach the light-emitting layer. When the metals such as silver and indium reaching the light-emitting layer form a filament-like conduction path, the conduction path could be the leakage path of the light-emitting layer in each of the light-emitting elements in the respective colors. As can be seen, when the metals such as silver and indium reaching the light-emitting layer form the filament-like leakage path, Joule heat conducted through the leakage could melt and break the filament-like leakage path in the light-emitting layer, and the light-emitting layer might disappear. Even in such a case, the metal halides MHa, MHa′, and MHa″ around the leakage path in the light-emitting layer melt and terminate the surface defects of the quantum dots QD.

Even in such a case, as to the display device, as described above, the metal halides MHa, MHa′, and MHa″ around the leakage path in the light-emitting layer could melt and terminate the surface defects of the quantum dots QD without a separate step of malting the metal halides MHa, MHa′ and MHa″.

The method for producing the red light-emitting element 5R illustrated in FIGS. 3 and 5 includes a step of forming the red light-emitting layer 24REM containing the red light-emitting quantum dots RQD containing the ligands L1, the ligands L2, and the metal halide MHa. As described above, the red light-emitting layer 24REM may omit the ligands L2. As described above, the metal halide MHa to be preferably used has a melting point of 200° C. or below. The metal halide MHa used in this embodiment is GaGl₃ having a melting point of 78° C. and a bandgap Bg of 4.3 eV.

At the step of forming the red light-emitting layer 24REM, the red light-emitting layer 24REM can be formed, using a quantum-dot solution containing: the red light-emitting quantum dots RQD containing the ligands L1; the ligands L2, the metal halide MHa; and a solvent. The quantum-dot solution is, for example, delivered in droplets on the hole transport layer 24HT by application or inkjet printing. Note that the red light-emitting quantum dots RQD containing the ligands L1 can be prepared of a quantum-dot solution containing: quantum dots not containing the ligands L1; the ligands L1 and L2; the metal halide MHa; and a solvent. Furthermore, before the quantum-dot solution is prepared, quantum dots not containing the ligands L1 may be processed with the ligands L1 to form the red light-emitting quantum dots RQD containing the ligands L1.

Example of the solvent may preferably include toluene, hexane, and octane in which the red light-emitting quantum dots RQD containing the ligands L1 and the metal halide MHa can disperse, and in which the ligands L2 can either melt or disperse. Moreover, if the ligands L1 and L2 are organic materials, the ligands L2 and the metal halide MHa are mixed together and possibly melt together in the solvent.

FIG. 8 is a cross-sectional view of a schematic configuration of another red light-emitting element 5R′ that can be included in the display device 1 according to the first embodiment.

FIG. 8 illustrates the red light-emitting element 5R′ in the reverse-order stack structure. The red light-emitting element 5R′ includes: the first electrode 22 serving as a cathode; and the second electrode 25 provided above the first electrode 22 and serving as an anode. The functional layer 24R′, including the red light-emitting layer 24REM provided between the first electrode 22 serving as a cathode and the second electrode 25 serving as an anode, can be formed of: the electron transport layer 24ET; the red light-emitting layer 24REM; the hole transport layer 24HT, and the hole injection layer 24HI, all of which are stacked on top of another in the stated order from toward the first electrode 22. The red light-emitting element 5R′ in the reverse-order stack structure also includes the red light-emitting layer 24REM containing the metal halide MHa. Similar to the red light-emitting element 5R in the forward-order stack structure, the metal halide MHa is melted and ionized so that the halogen ions Ha-exhibit an increase in movement and terminate the surface defects of the red light-emitting quantum dots RQD.

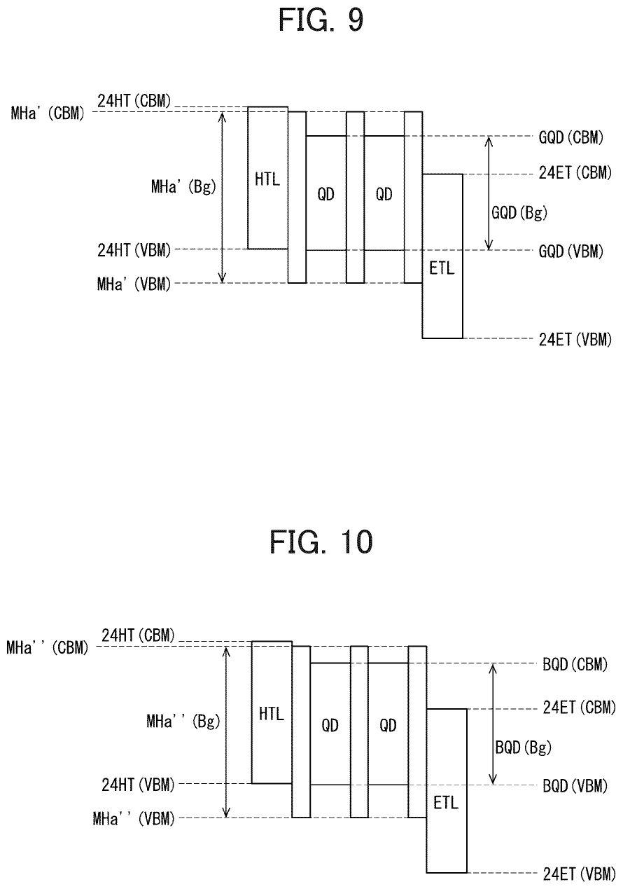

FIG. 9 is a diagram illustrating band levels of the hole transport layer 24HT, the electron transport layer 24ET, green light-emitting quantum dots GQD, and a metal halide MHa′, all of which are included in the green light-emitting element 5G of the display device 1 according to the first embodiment.

A not-shown green light-emitting layer included in the green light-emitting element 5G of the display device 1 according to the first embodiment contains: the green light-emitting quantum dots GQD containing the ligands L1; the ligands L2; and the metal halide MHa′.

This embodiment exemplifies a case where the green light-emitting layer contains the ligands L2. However, this embodiment shall not be limited to such a case. The green light-emitting layer may omit the ligands L2, and may contain the green light-emitting quantum dots GQD containing the ligands L1 and the metal halide MHa′.

As illustrated in FIG. 9, regarding the metal halide MHa′ to be preferably used, a bandgap of the metal halide MHa′ (MHa′ (Bg)) representing a difference between a valence band maximum of the metal halide MHa′ (MHa′ (VBM)) and a conduction band minimum of the metal halide MHa′ (MHa′ (CBM)) is larger than, or equal to, a bandgap of the green light-emitting quantum dots GQD (GQD (Bg)) representing a difference between a valence band maximum of the green light-emitting quantum dots GQD (GQD (VBM)) and a conduction band minimum of the green light-emitting quantum dots GQD (GQD (CBM)). This embodiment exemplifies a case where the valence band maximum of the metal halide MHa′ (MHa′ (VBM)) is deeper than the valence band maximum of the green light-emitting quantum dots GQD (GQD (VBM)), and where the conduction band minimum of the metal halide MHa′ (MHa′ (CBM)) is shallower than the conduction band minimum of the green light-emitting quantum dots GQD (GOD (CBM)). However, this embodiment shall not be limited to such a case. As can be seen, the metal halide MHa′ to be used has a bandgap larger than the bandgap of the green light-emitting quantum dots GQD (GQD (Bg)). Such a feature can reduce current leakage that could occur among the plurality of light-emitting elements through the metal halide MHa′. This embodiment exemplifies a case where the green light-emitting quantum dots GQD to be used has a valence band maximum (GQD (VBM)) of −5.6 eV, a conduction band minimum (GQD (CBM)) of −3.3 eV, and a bandgap (GQD (Bg)) of 2.3 eV. However, this embodiment shall not be limited to such a case.

Furthermore, the metal halide MHa′ contained in the green light-emitting layer included in the green light-emitting element 5G of this embodiment is more preferably a metal halide: selected from, for example, the various kinds of metal halides shown in FIG. 11; and having a bandgap (MHa′ (Ba)) larger than, or equal to, the bandgap of the green light-emitting quantum dots GQD (e.g., GQD (Bg)=2.3 eV), wherein the bandgap of the metal halide MHa′ is smaller than a value (e.g., 6.9 eV) three times as large as the bandgap of the green light-emitting quantum dots GQD (e.g., GQD (Bg)=2.3 eV). As can be seen, the bandgap of the halide MHa′ (MHa′ (Bg)) is set smaller than a value three times as large as the bandgap of the green light-emitting quantum dots GQD (GQD (Bg)). Such a feature can reduce a deterioration in electric characteristic of the green light-emitting element 5G.

Furthermore, this embodiment exemplifies a case where the metal halide MHa′ contained in the green light-emitting layer included in the green light-emitting element 5G is GaCl₃ having a melting point of 78° C. and a bandgap Bg of 4.3 eV, similar to the metal halide MHa contained in the red light-emitting layer 24REM included in the red light-emitting element 5R. However, this embodiment shall not be limited to such a case. The metal halide MHa′ contained in the green light-emitting layer included in the green light-emitting element 5G and the metal halide MHa contained in the red light-emitting layer 24REM included in the red light-emitting element 5R may be different metal halides.

FIG. 10 is a diagram illustrating band levels of the hole transport layer 24HT, the electron transport layer 24ET, blue light-emitting quantum dots BQD, and a metal halide MHa″, all of which are included in the blue light-emitting element 5B of the display device 1 according to the first embodiment.

A not-shown blue light-emitting layer included in the blue light-emitting element 5B of the display device 1 according to the first embodiment contains: the blue light-emitting quantum dots BQD containing the ligands L1; the ligands L2; and the metal halide MHa″.

This embodiment exemplifies a case where the blue light-emitting layer contains the ligands L2. However, this embodiment shall not be limited to such a case. The blue light-emitting layer may omit the ligands L2, and may contain the blue light-emitting quantum dots BQD containing the ligands L1 and the metal halide MHa″.

As illustrated in FIG. 10, regarding the metal halide MHa″ to be preferably used, a bandgap of the metal halide MHa″ (MHa″ (Bg)) representing a difference between a valence band maximum of the metal halide MHa″ (MHa″ (VBM)) and a conduction band minimum of the metal halide MHa″ (MHa″ (CBM)) is larger than, or equal to, a bandgap of the blue light-emitting quantum dots BQD (BQD (Bg)) representing a difference between a valence band maximum of the blue light-emitting quantum dots BQD (BQD (VBM)) and a conduction band minimum of the blue light-emitting quantum dots BQD (BQD (CBM)). This embodiment exemplifies a case where the valence band maximum of the metal halide MHa″ (MHa″ (VBM)) is deeper than the valence band maximum of the blue light-emitting quantum dots BQD (BQD (VBM)), and where the conduction band minimum of the metal halide MHa″ (MHa″ (CBM)) is shallower than the conduction band minimum of the blue light-emitting quantum dots BQD (BQD (CBM)). However, this embodiment shall not be limited to such a case. As can be seen, the metal halide MHa″ to be used has a bandgap larger than the bandgap of the blue light-emitting quantum dots BQD (BQD (Bg)). Such a feature can reduce current leakage that could occur among the plurality of light-emitting elements through the metal halide MHa″. This embodiment exemplifies a case where the blue light-emitting quantum dots BQD to be used has a valence band maximum (BQD (VBM)) of −5.6 eV, a conduction band minimum (BQD (CBM)) of −2.8 eV, and a bandgap (BQD (Bg)) of 2.8 eV. However, this embodiment shall not be limited to such a case.

Furthermore, the metal halide MHa″ contained in the blue light-emitting layer included in the blue light-emitting element 5B of this embodiment is more preferably a metal halide: selected from, for example, the various kinds of metal halides shown in FIG. 11; and having a bandgap (MHa″ (Ba)) larger than, or equal to, the bandgap of the blue light-emitting quantum dots BQD (e.g., BQD (Bg)=2.8 eV), wherein the bandgap of the metal halide MHa″ is smaller than a value (e.g., 8.4 eV) three times as large as the bandgap of the blue light-emitting quantum dots BQD (e.g., BQD (Bg)=2.8 eV). As can be seen, the bandgap of the halide MHa″ (MHa″ (Bg)) is set smaller than a value three times as large as the bandgap of the blue light-emitting quantum dots BQD (BQD (Bg)). Such a feature can reduce a deterioration in electric characteristic of the blue light-emitting element 5B.

Furthermore, this embodiment exemplifies a case where the metal halide MHa″ contained in the blue light-emitting layer included in the blue light-emitting element 5B is GaCl₃ having a melting point of 78° C. and a bandgap Bg of 0.43 eV, similar to the metal halide MHa contained in the red light-emitting layer 24REM included in the red light-emitting element 5R and the metal halide MHa′ contained in the green light-emitting layer included in the green light-emitting element 5G. However, this embodiment shall not be limited to such a case. The metal halide MHa″ contained in the blue light-emitting layer included in the blue light-emitting element 5B, the metal halide MHa contained in the red light-emitting layer 24REM included in the red light-emitting element 5R, and the metal halide MHa′ contained in the green light-emitting layer included in the green light-emitting element 5G may be different metal halides.

This embodiment exemplifies a case where, as to the colored light-emitting layers included in the colored light-emitting elements 5R, 5G, and 5G of the display device 1, each of the light-emitting layers contains: the quantum dots containing the ligands L1; the ligands L2; and a metal halide. However, this embodiment shall not be limited to such a case. Among the colored light-emitting layers included in the colored light-emitting elements 5R, 5G, and 5B of the display device 1, a light-emitting layer in a specific color alone; that is, for example, the red light-emitting layer alone, may contain: the quantum dots containing the ligands L1; the ligands L2; and a metal halide. The remaining green light-emitting layer and blue light-emitting layer may each omit a metal halide, and contain the quantum dots containing the ligands L1, and the ligands L2.

Thanks to the light-emitting elements 5R, 5R′, 5G, and 5B, the display device 1, the methods for producing the light-emitting elements 5R, 5R′,5G, and 5B, and the methods for restoring emission characteristics of the light-emitting elements 5R, 5R′, 5G, and 5B, the light-emitting layers containing quantum dots can achieve improvement in long-term reliability and restore their decreased emission characteristics (light emission efficiency).

### Second Embodiment

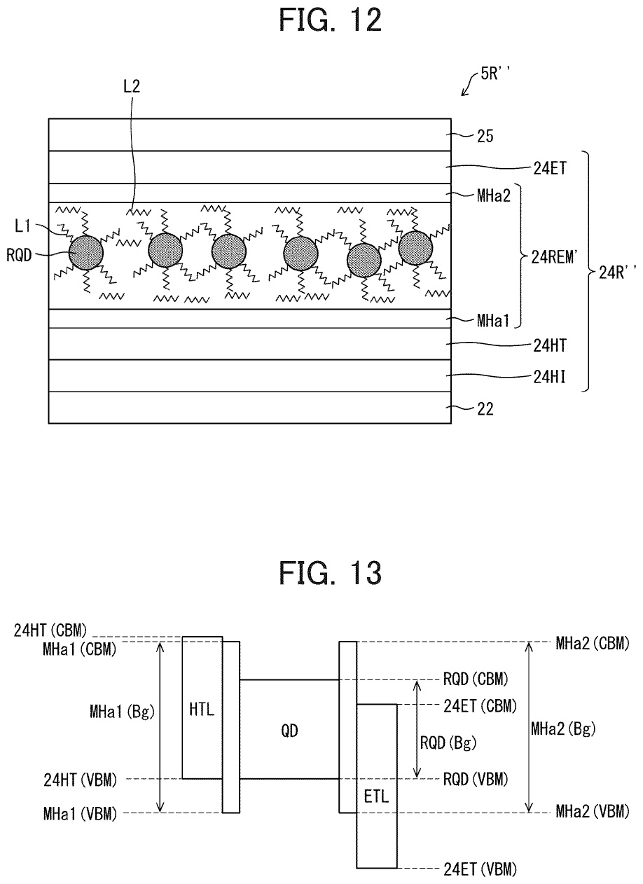

Described next is a second embodiment of present disclosure, with reference to FIGS. 12 to 15. A red light-emitting element 5R″ included in a display device according to this embodiment is different from the colored light-emitting elements included in the display device 1 described in the first embodiment in that, in the red light-emitting element 5R″, a red light-emitting layer 24REM′ includes: a quantum dot layer containing the red light-emitting quantum dots RQD containing the ligands L1, and the ligands L2; and one or more metal halide layers MHa1 and MHa2 containing the metal halide MHa. Otherwise, the red light-emitting element 5R″ is the same as the light-emitting elements of the first embodiment. For convenience in description, like reference signs designate identical constituent features throughout the drawings between this embodiment and the first embodiment. These constituent features will not be elaborated upon.

FIG. 12 is a cross-sectional view illustrating a schematic configuration of the red light-emitting element 5R″ included in the display device according to the second embodiment. The red light-emitting element 5R″ illustrated in FIG. 12 is in an initial state in which the red light-emitting element 5R″ is either before driven or driven for a relatively short time.

As illustrated in FIG. 12, the red light-emitting layer 24REM′ included in the red light-emitting element 5R″ includes: the quantum dot layer containing the red light-emitting quantum dots RQD containing the ligands L1, and the ligands L2; the metal halide layer MHa1 provided below the quantum dot layer and containing the metal halide MHa; and the metal halide layer MHa2 provided above the quantum dot layer and containing the metal halide MHa.

This embodiment exemplifies a case where the quantum dot layer of the red light-emitting layer 24REM′ contains the ligands L2. However, this embodiment shall not be limited to such a case. The quantum dot layer of the red light-emitting layer 24REM′ may omit the ligands L2.

Furthermore, this embodiment exemplifies a case where the red light-emitting layer 24REM′ includes two layers; namely, the metal halide layer MHa1 and the metal halide layer MHa2. However, this embodiment shall not be limited to such a case. The red light-emitting layer 24REM′ may include one layer alone out of the two layers; namely, the metal halide layer MHa1 and the metal halide layer MHa2, and two or more metal halide layers containing the metal halide MHa may be stacked at least one of above or below the quantum dot layer.

Moreover, this embodiment exemplifies a case where the metal halide MHa contained in the metal halide layer MHa1 and the metal halide MHa contained in the metal halide layer MHa2 are the same metal halide. However, this embodiment shall not be limited to such a case. The metal halide MHa contained in the metal halide layer MHa1 and the metal halide MHa contained in the metal halide layer MHa2 may be different metal halides.

This embodiment exemplifies a case where, similar to the first embodiment described above, the metal halide MHa is GaCl₃ having a melting point of 78° C. and a bandgap Bg of 4.3 eV, and the ligands L1 and the ligands L2 are trioctylphosphine (TOP); that is, organic ligands having a melting point of 30° C. and a boiling point of 234° C. However, this embodiment shall not be limited to such case.

FIG. 13 is a diagram illustrating band levels of the hole transport layer 24HT, the electron transport layer 24ET, the red light-emitting quantum dots RQD containing the ligands L1, and the metal halide layers MHa 1 and MHa2 containing the metal halide MHa, all of which are included in the red light-emitting element 5R″ illustrated in FIG. 12.

As illustrated in FIG. 13, regarding the metal halide MHa to be preferably used, bandgaps of the metal halide layers MHa1 and MHa2 (MHa1 (Bg) and MHa2 (Bg)) representing differences between valence band maximums of the metal halide layers MHa1 and MHa2 (MHa1 (VBM) and MHa2 (VBM)) and conduction band minimums of the metal halide layers MHa1 and MHa 2 (MHa1 (CBM) and MHa2 (CBM)) are larger than, or equal to, the bandgap of the red light-emitting quantum dots RQD (RQD (Bg)) representing a difference between a valence band maximum of the red light-emitting quantum dots RQD (RQD (VBM)) and a conduction band minimum of the red light-emitting quantum dots RQD (RQD (CBM)). This embodiment exemplifies a case where the valence band maximums of the metal halide layers MHa1 and MHa2 (MHa1 (VBM) and MHa2 (VBM)) are deeper than the valence band maximum of the red light-emitting quantum dots RQD (RQD (VBM)), and where the conduction band minimums of the metal halide layers MHa1 and MHa2 (MHa1 (CBM) and MHa2 (CBM)) are shallower than the conduction band minimum of the red light-emitting quantum dots RQD (RQD (CBM)). However, this embodiment shall not be limited to such a case. As can be seen, the metal halide layers MHa1 and MHa2 to be used have bandgaps larger than the bandgap of the red light-emitting quantum dots RQD (RQD (Bg)). Such a feature can reduce current leakage that could occur among the plurality of light-emitting elements through the metal halide layers MHa1 and MHa2.

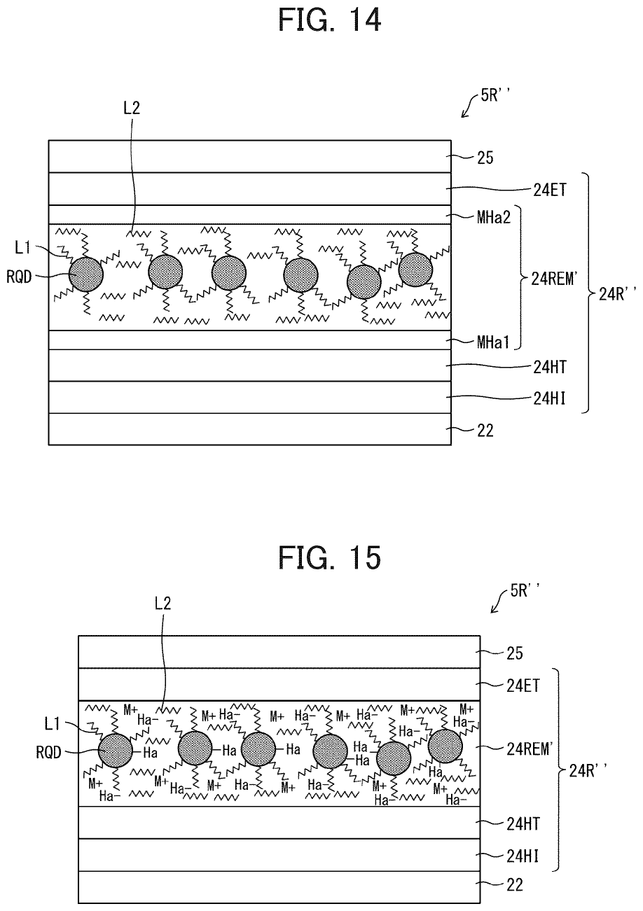

FIG. 14 is a diagram showing how the red light-emitting layer 24REM′ changes over time after the red light-emitting element 5R″ illustrated in FIG. 12 has been driven for a predetermined time period.

Compared with the red light-emitting layer 24REM′ included in the red light-emitting element 5R″ in the initial state in FIG. 12, the red light-emitting layer 24REM′ included in the red light-emitting element 5R″ after driven for the predetermined time period illustrated in FIG. 14 shows that the ligands L1 disposed either on or near the surface of the red light-emitting quantum dots RQD are desorbed with the passage of time and the stress of drive by a current. The desorption results in a decrease in the number of the ligands LI per one red light-emitting quantum dot RQD. Originally, the ligands L2 play a role of compensating for the ligands L1 desorbed from the surface of, or near the surface of, the red light-emitting quantum dots RQD. However, as described above, the ligands L2 are found in a liquid state in the light-emitting layer under the normal light-emitting-element drive condition. Hence, the ligands L2 illustrated in FIG. 12 gradually vaporizes with the passage of time, and that is why the extra ligands L2 for compensating for the desorbed ligands L1 run short. Hence, the red light-emitting quantum dots RQD are deactivated because of the surface defects. The deactivation makes it difficult to ensure the long-term reliability of the red light-emitting element 5R″. The deactivation also makes it impossible to avoid a decrease in emission characteristic (light emission efficiency) of the quantum dot layer containing the red light-emitting quantum dots RQD, which occurs with the passage of time.

FIG. 15 is a diagram showing, as to the red light-emitting layer 24REM′ of the red light-emitting element 5R″ illustrated in FIG. 14 and changed over time, how the metal halide layers MHa1 and MHa2 contained in the red light-emitting layer 24REM′ are melted and an emission characteristic (light emission efficiency) of the red light-emitting element 5R″ is restored.

Hence, as illustrated in FIG. 15, a step is carried out to melt the metal halide layers MHa1 and MHa2 contained in the red light-emitting layer 24REM′ included in the red light-emitting element 5R″ driven for a predetermined time period. That is, a method including the step of melting the metal halide MHa is carried out to restore an emission characteristic (light emission efficiency) of the red light-emitting element 5R″. The step of melting the metal halide layers MHa1 and MHa2 is the same as the step of melting the metal halide MHa described above in the first embodiment, and thus the description thereof will be omitted here.

A step of forming the red light-emitting layer 24REM′ illustrated in FIG. 12 includes: a step of forming the quantum dot layer containing the red light-emitting quantum dots RQD containing the ligands L1, and the ligands L2; and a step of forming the metal halide layers MHa1 and MHa2 containing the metal halide MHa, using a metal halide solution containing the metal halide MHa and a solvent.

In this embodiment, for example, the metal halide layer MHa1 containing the metal halide MHa is formed on the hole transport layer 24HT. After that, a quantum dot layer is formed to contain: the red light-emitting quantum dots RQD containing the ligands L1; and the ligands L2. After that, the metal halide layer MHa2 containing the metal halide MHa is formed. Thus, the red light-emitting layer 24REM′ is formed.

Thanks to the light-emitting element 5R″, the display device including the light-emitting element 5R″, the method for producing the light-emitting element 5R″, and the method for restoring emission characteristic of the light-emitting element 5R″, the light-emitting layer containing quantum dots can achieve improvement in long-term reliability and restore its decreased emission characteristics (light emission efficiency).

### Third Embodiment

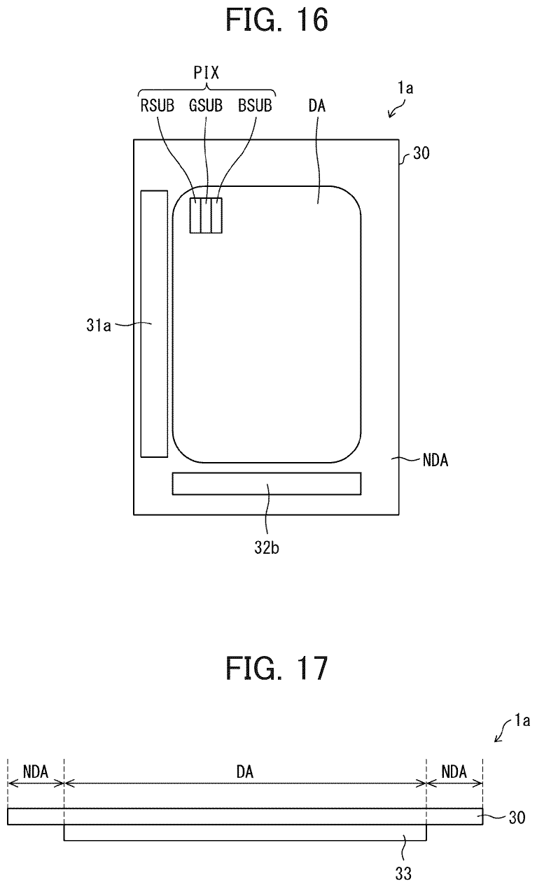

Described next is a third embodiment of present disclosure, with reference to FIGS. 16 and 17. A display device la of this embodiment differs from the display devices described in the first and second embodiments in that the display device la includes a heating unit 33 for performing a step of melting the metal halide MHa. Otherwise, the display device la is the same as the display devices of the first and second embodiments. For convenience in description, like reference signs designate identical constituent features throughout the drawings between this embodiment and the first and second embodiments. These constituent features will not be elaborated upon.

FIG. 16 is a plan view illustrating a schematic configuration of the display device la according to the third embodiment.

FIG. 17 illustrates the heating unit 33 included in the display device la illustrated in FIG. 16 according to the third embodiment.

As illustrated in FIG. 17, the display device la includes the heating unit 33 for performing the step of melting the metal halide MHa.

This embodiment exemplifies a case where the display device la separately includes the heating unit 33 for performing the step of melting the metal halide MHa, and where the scan drive circuit 31a and the data drive circuit 32a omit a mode for performing the step of melting the metal halide MHa. However, this embodiment shall not be limited to such a case. Similar to the first and second embodiments, the scan drive circuit 31a and the data drive circuit 32a 1a may include a mode for performing the step of melting the metal halide MHa.

As illustrated in FIG. 17, the heating unit 33 may be provided to overlap only with a display region DA of a display panel 30 because the heating unit 33 heats a region including the metal halide MHa. However, the heating unit 33 may be provided in any given manner.

If the heating unit 33 is separately included as seen in the display device la, such a feature can readily raise the temperature of a light-emitting element to a relatively high temperature, compared with a technique, described in the first and second embodiment, to vary the current density to control the temperature of the light-emitting element.

Furthermore, if the heating unit 33 is separately included as seen in the display device la, a step can be carried out to melt the metal halide MHa before formation of the constituent features up to the second electrode 25 of the light-emitting element. For example, the electron transport layer 24ET is formed on the red light-emitting layer 24REM included in the red light-emitting element 5R illustrated in FIG. 3. After that, a step may be carried out to melt the metal halide MHa. That is, a step of melting the metal halide MHa may be carried out during a step of producing the light-emitting element.

Note that, as seen in the display device la, suppose a case where the heating unit 33 is separately provided for performing the step of melting the metal halide MHa. If the display panel 30 is highly resistant to heat, a metal halide having a melting point of above 200° C. may be used among the various metal halides shown in FIG. 11.

For example, the display panel 30 can be provided with high heat resistance if an organic layer included in the display panel 30 is replaced with an inorganic layer, and an organic layer that can be omitted is omitted. For example, in the light-emitting element, the hole injection layer 24HI is omitted, the hole transport layer 24HT is formed of NiO particles, the electron transport layer 24ET is formed of ZnO particles, the ligands L1 are inorganic ligands (e.g., halogen ligands), and the ligands L2 are omitted. As a result, the light-emitting element can be provided with high heat resistance.

Whereas, metal halides serving as the metal halides MHa, MHa′, and MHa″ preferably have a melting point of 130° C. or below, and, more preferably, a melting point of 100° C. or below. If the metal halides MHa, MHa′ and MHa″ have a melting point of 130° C. or below, a step of melting the metal halides MHa, MHa′ and MHa″ can be carried out at 130° C. or below. Typically, the highest temperature in the element forming process is often 130° C. or below, which is the boiling point of an organic solvent (e.g., octane, chlorobenzene, and toluene). The step of melting the metal halides MHa, MHa′, and MHa″ is also carried out at 130° C. or below, thereby successfully reducing adverse effects on the elements included in the display device. Furthermore, if the metal halides MHa, MHa′ and MHa″ have a melting point of 100° C. or below, the step of melting the metal halides MHa, MHa′ and MHa″ can be carried out at 100° C. or below. Hence, if the step of melting the metal halides MHa, MHa′, and MHa″ is carried out at 100° C. or below, the step can reduce adverse effects on other electronic components included in the display device.

### Additional Remarks

The present disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the present disclosure. Moreover, the technical aspects disclosed in each embodiment may be combined together to achieve a new technical feature.

### INDUSTRIAL APPLICABILITY

The present disclosure can be used for a light-emitting element, a display device, a method for producing the light-emitting element, and a method for restoring an emission characteristic of the light-emitting element.

1. A light-emitting element, comprising:
a first electrode;
a second electrode; and
a light-emitting layer provided between the first electrode and the second electrode,
wherein the light-emitting layer contains: quantum dots; and a metal halide having a melting point of 200° C. or below.

2. The light-emitting element according to claim 1,
wherein the light-emitting layer is a single layer in which the quantum dots and the metal halide are mixed together.

3. The light-emitting element according to claim 1,
wherein the light-emitting layer includes:
a quantum dot layer containing the quantum dots; and
one or more metal halide layers containing the metal halide.

4. The light-emitting element according to claim 1,
wherein the light-emitting layer contains organic ligands having a melting point of 50° C. or below.

5. The light-emitting element according to claim 1,
wherein a bandgap of the metal halide is larger than, or equal to, a bandgap of the quantum dots.

6. The light-emitting element according to claim 5,
wherein the bandgap of the metal halide is smaller than a value three times as large as the bandgap of the quantum dots.

7. The light-emitting element according to claim 1,
wherein a bandgap of the metal halide is 3.4 eV or larger and 5.3 eV or smaller.

8. The light-emitting element according to claim 1,
wherein a melting point of the metal halide is higher than 50° C.

9. The light-emitting element according to claim 1,
wherein the light-emitting layer further contains: a second metal halide different in kind from the metal halide.

10. The light-emitting element according to claim 1,
wherein, between the first electrode and the second electrode, a current flows at a current density of 30 mA/cm² or higher.

11. A display device, comprising:
a display panel including the light-emitting element according to claim 1; and a drive circuit,
wherein, in accordance with a video signal input from outside, the drive circuit supplies a current, between the first electrode and the second electrode, at a current density selected within a first current density range, and causes the light-emitting layer to emit light at a luminance corresponding to the selected current density, and
a melting point of the metal halide is higher than a temperature observed of the light-emitting element when the current is supplied between the first electrode and the second electrode at the selected current density.

12. The display device according to claim 11,
wherein the drive circuit supplies a current, between the first electrode and the second electrode, at a current density selected in a second current density range having a value larger than a value of the first current density range, and raises the temperature of the light-emitting element higher than the melting point of the metal halide.

13. A display device, comprising:
a display panel including the light-emitting element according to claim 1; and
a heating unit configured to raise a temperature of the light-emitting element higher than a melting point of the metal halide.

14. A method for producing a light-emitting element, the method comprising
a step of forming a light-emitting layer containing: quantum dots; and a metal halide having a melting point of 200° C. or below.

15. The light-emitting element manufacturing method according to claim 14,
wherein, at the step of forming the light-emitting layer, the light-emitting layer is formed, using a quantum dot solution containing the quantum dots, the metal halide, and a solvent.

16. The method for producing the light-emitting element according to claim 14,
wherein the step of forming the light-emitting layer includes:
a step of forming a quantum dot layer containing the quantum dots; and
a step of forming a metal halide layer containing the metal halide, using a metal halide solution containing the metal halide and a solvent.

17. The method for producing the light-emitting element according to claim 1, further comprising
a step of melting the metal halide.

18. A method for restoring an emission characteristic of the light-emitting element produced by the method according to claim 14, the method for restoring the emission characteristic comprising
a step of melting the metal halide.
